(19) United States
(12) Patent Application Publication
(10) Pub. No.: US 2008/0283895 A1
(43) Pub. Date: Nov. 20, 2008

(54) Memory structure and fabricating method thereof

(75) Inventors: Ching-Nan Hsiao, Kaohsiung County (TW); Ying-Cheng Chuang, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 11/953,882

(22) Filed: Dec. 11, 2007

(30) Foreign Application Priority Data
May 18, 2007 (TW) 96117797

(51) Int. Cl. H01L 29/00; H01L 21/425

(52) U.S. Cl. 257/315; 438/531; 257/E21.473; 257/E29.3

(57) ABSTRACT

A memory structure including a substrate, dielectric patterns, spacer patterns, a first dielectric layer, a conductor pattern, a second dielectric layer and doped regions is described. The dielectric patterns are disposed on the substrate. The spacer patterns are disposed on each sidewall of each of the dielectric patterns respectively. The first dielectric layer is disposed between the spacer patterns and the substrate. The conductor pattern is disposed on the substrate and covers the spacer patterns. The second dielectric layer is disposed between the spacer patterns and the conductor pattern. The doped regions are disposed in the substrate under each of the dielectric patterns respectively.

### CROSS-REFERENCE TO RELATED APPLICATION

This application claims the priority benefit of Taiwan application serial no. 96117797, filed on May 18, 2007. The entirety of the above-mentioned patent application is hereby incorporated by reference herein and made a part of this specification.

### BACKGROUND OF THE INVENTION

1. Field of the Invention

The present invention relates to a memory structure and a fabricating method thereof. More particularly, the present invention relates to a flash memory structure and a fabricating method thereof.

2. Description of Related Art

A flash memory is a type of non-volatile memory that allows multiple data writing, reading and erasing operations. The stored data will be retained even after power to the device is off. With these advantages, the flash memory has become one of the most widely adopted memory devices for personal computers and electronic equipment.

A typical flash memory has a floating gate and a control gate fabricated using doped polysilicon. The floating gate is disposed between the control gate and a substrate and in a floating state. Namely, the floating gate is not electrically connected to any circuit. The control gate is electrically connected to a word line. In addition, the typical flash memory further comprises a tunneling oxide layer and an inter-gate dielectric layer, wherein the tunneling oxide layer is disposed between the substrate and the floating gate, and the inter-gate dielectric layer is located between the floating gate and the control gate. When programming the memory, since electrons injected into the floating gate are uniformly distributed to the entire polysilicon floating gate layer, the memory cell is a 1-bit cell memory cell merely capable of storing two data storage states, either “0” or “1”.

However, along the increase of the data stored in the memory, the 1-bit cell storage cannot satisfy the demand for high-density data storage, and therefore a flash memory capable of executing multi-bit storage in a single memory cell is needed.

### SUMMARY OF THE INVENTION

Accordingly, the present invention is directed to provide a memory structure capable of storing two bits of data in a single memory cell.

The present invention is further directed to provide a fabricating method for a memory device so that the process complexity and the process time for fabricating floating gates are reduced.

The present invention provides a memory structure which comprises a substrate, a plurality of dielectric patterns, a plurality of spacer patterns, a first dielectric layer, a plurality of conductor patterns, a second dielectric layer and a plurality of doped regions. The dielectric patterns are disposed on the substrate. The spacer patterns are respectively disposed on sidewalls of each of the dielectric patterns. The first dielectric layer is disposed between the spacer patterns and the substrate. The conductor patterns are disposed on the substrate and cover the spacer patterns. The second dielectric layer is disposed between the spacer patterns and the conductor patterns. The doped regions are respectively disposed in the substrate under each of the dielectric patterns.

According to one embodiment of the present invention, in the foregoing memory structure, the substrate comprises a silicon substrate.

According to one embodiment of the present invention, in the foregoing memory structure, the material of the dielectric patterns comprises silicon oxide.

According to one embodiment of the present invention, in the foregoing memory structure, the material of the spacer patterns comprises polysilicon.

According to one embodiment of the present invention, in the foregoing memory structure, the material of the first dielectric layer comprises silicon oxide.

According to one embodiment of the present invention, in the foregoing memory structure, the material of the conductor patterns comprises polysilicon.

According to one embodiment of the present invention, in the foregoing memory structure, the second dielectric layer comprises a silicon oxide/silicon nitride/silicon oxide compound layer.

The present invention provides a fabricating method for a memory structure, the fabricating method comprising the following steps. First, a plurality of doped regions is formed on a substrate. Next, a first dielectric layer is formed on the substrate. Then, a plurality of dielectric patterns is formed on the substrate above the doped regions respectively. Moreover, a spacer is formed on each sidewall of each of the dielectric patterns respectively. Then, a second dielectric layer is formed on the spacers. After that, a first conductive layer is formed on the substrate and covers the second dielectric layer. Thereafter, a first patterning process is performed on the first conductive layer and the spacers so that the first conductive layer is patterned into a conductor pattern, and meanwhile, the spacers are patterned into a plurality of spacer patterns.

According to one embodiment of the present invention, in the foregoing fabricating method for a memory structure, the method for forming the doped regions comprises the following steps. First, a plurality of mask patterns is formed on the substrate. Next, an ion implantation process is performed on the substrate by using the mask patterns as a mask. Then, the mask patterns are removed.

According to one embodiment of the present invention, in the foregoing fabricating method for a memory structure, the method for forming the mask patterns comprises the following steps. First, a mask layer is formed on the substrate. Next, a second patterning process is performed on the mask layer.

According to one embodiment of the present invention, in the foregoing fabricating method for a memory structure, the method for forming the dielectric patterns comprises the following steps. First, a plurality of mask patterns is formed on the substrate, and a trench is formed between two adjacent mask patterns. Next, a third dielectric layer is formed on the substrate and the third dielectric layer fills up the trenches. Then, a part of the third dielectric layer out side of the trenches is removed. Thereafter, the mask patterns are removed.

According to one embodiment of the present invention, in the foregoing fabricating method for a memory structure, the method for removing the part of the third dielectric layer comprises performing a chemical mechanical polishing process.

According to one embodiment of the present invention, in the foregoing fabricating method for a memory structure, the method for forming the first dielectric layer comprises performing a thermal oxidation process.

According to one embodiment of the present invention, in the foregoing fabricating method for a memory structure, the method for forming the spacers comprises the following steps. First, a second conductive layer is formed on the substrate and covers the dielectric patterns. Next, an etch-back process is performed on the second conductive layer.

According to one embodiment of the present invention, in the foregoing fabricating method for a memory structure, the method for forming the second conductive layer comprises performing a chemical vapor deposition process.

According to one embodiment of the present invention, in the foregoing fabricating method for a memory structure, the etch-back process comprises a dry etching process.

According to one embodiment of the present invention, in the foregoing fabricating method for a memory structure, the second dielectric layer comprises a silicon oxide layer, a silicon nitride layer or a silicon oxide/silicon nitride/silicon oxide compound layer.

According to one embodiment of the present invention, in the foregoing fabricating method for a memory structure, the method for forming the first conductive layer comprises performing a chemical vapor deposition process.

Based on the above, in the memory structure provided by the present invention, since the spacer patterns are respectively disposed on the sidewalls of each of the dielectric patterns, a single cell has two floating gates as a storage unit so that a single cell can store two bits of data, which effectively increases the cell capacity.

In addition, in the fabricating method for the memory structure provided by the present invention, since floating gates are formed by using the method for forming the spacers, the process complexity and the process time are reduced so that the memory structure capable of storing two bits of data in a single cell can be easily fabricated.

In order to make the aforementioned and other objects, features and advantages of the present invention comprehensible, embodiments accompanied with figures are described in details below. It is to be understood that both the foregoing general description and the following detailed description are exemplary and are intended to provide further explanation of the invention as claimed.

### BRIEF DESCRIPTION OF THE DRAWINGS

FIG. 1 is a top view of a memory structure according to one embodiment of the present invention.

FIG. 2 is a cross-sectional view along line A-A′ in FIG. 1.

FIG. 3A to FIG. 3D are cross-sectional views showing the steps for fabricating a memory structure according to one embodiment of the present invention.

### DESCRIPTION OF EMBODIMENTS

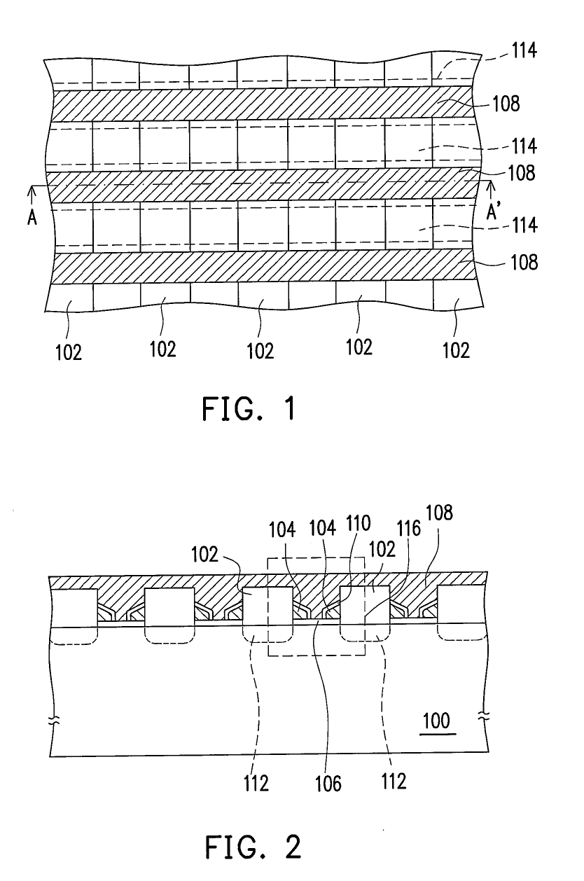

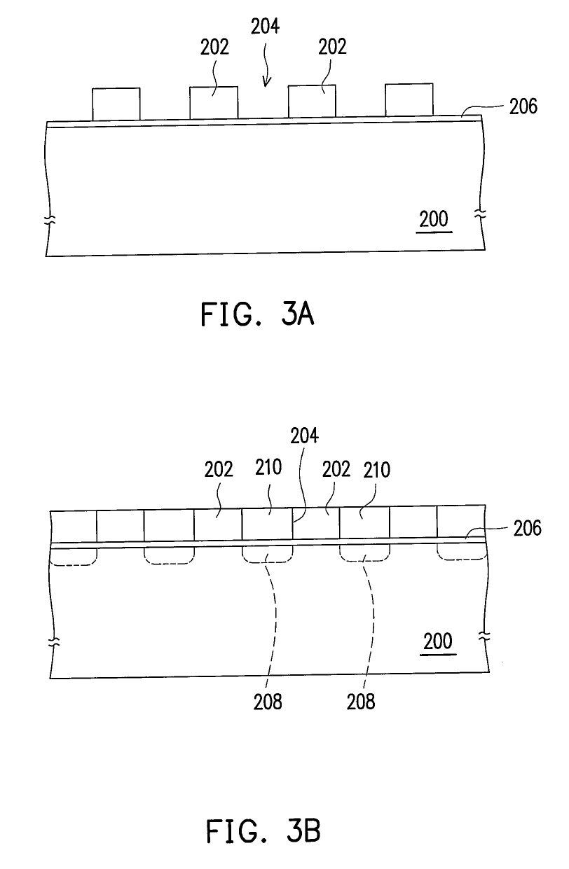

FIG. 1 is a top view of a memory structure according to one embodiment of the present invention. FIG. 2 is a cross-sectional view along line A-A′ in FIG. 1.

With reference to FIG. 1 and FIG. 2, the memory structure comprises a substrate 100, a plurality of dielectric patterns 102, a plurality of spacer patterns 104, a first dielectric layer 106, a plurality of conductor patterns 108, a second dielectric layer 110 and a plurality of doped regions 112.

A plurality of isolation structures 114 is formed on the substrate 100. The substrate 100 is, for example, a silicon substrate. The isolation structures 114 are shallow trench isolation structures, for example.

The dielectric patterns 102 are disposed on the substrate 100 to separate two adjacent memory cells 116. The material of the dielectric patterns 102 is, for example, silicon oxide.

The spacer patterns 104 disposed on the sidewalls of the dielectric patterns 102 serve as floating gates. The material of the spacer patterns 104 is, for example, polysilicon.

The first dielectric layer 106 disposed between the spacer patterns 104 and the substrate 100 and between the conductor patterns 108 and the substrate 100 serves as a tunneling dielectric layer. The material of the first dielectric layer 106 is, for example, silicon oxide.

The conductor patterns 108 disposed on the substrate 100 and covering the spacer patterns 104 serve as control gates. The material of the conductor patterns 108 is, for example, polysilicon.

The second dielectric layer 110 disposed between the spacer patterns 104 and the conductor patterns 108 serves as an inter-gate dielectric layer. The second dielectric layer 110 is, for example, a single-layered silicon oxide layer. Certainly, the second dielectric layer 110 can also be a silicon nitride layer, a silicon oxide/silicon nitride compound layer, a silicon oxide/silicon nitride/silicon oxide compound layer or other suitable film layers.

The doped regions 112 disposed in the substrate 100 under the dielectric patterns 102 serve as source regions and drain regions.

In the foregoing embodiments, since the single memory cell 116 has two spacer patterns 104 disposed on the sidewalls of the dielectric pattern 102, the single cell 116 has two storage units so that the single memory cell 116 can store two bits of data, which increases the cell capacity.

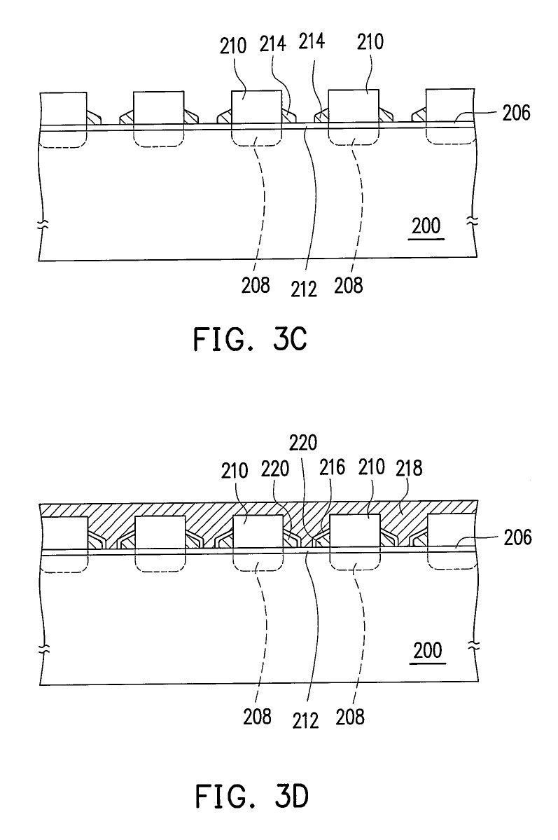

FIG. 3A to FIG. 3D are cross-sectional views showing the steps for fabricating a memory structure according to one embodiment of the present invention. Wherein, the directions of the cross-sectional views from FIG. 3A to FIG. 3D are the same as the direction of the line A-A′ in FIG. 1.

First, a plurality of mask patterns 202 is formed on a substrate 200, and a trench 204 is formed between two adjacent mask patterns 202. The material of the mask patterns 202 is, for example, nitride silicon. The method for forming the mask patterns 202 is, for example, performing a chemical vapor deposition process to form a mask layer (not illustrated) on the substrate 200, wherein the mask layer is an insulating layer, for example. The insulating layer is, for example, a silicon nitride layer, formed by performing a patterning process on the mask layer, wherein the patterning process is performed, for example, by implementing a photolithography process and an etching process.

Furthermore, a pad oxide layer 206 on the substrate 200 before forming the mask patterns 202 is selectively formed. The pad oxide layer 206 can prevent the mask patterns 202 from generating stress on the substrate 200 and can enhance the adhesion force between the mask patterns 202 and the substrate 200. The material of the pad oxide layer 206 is, for example, silicon oxide. The method for forming the pad oxide layer 206 is by performing a thermal oxidation process, for example.

Then, with reference to FIG. 3B, a plurality of doped regions 208 is formed in the substrate 200 and the doped regions are used as source regions and drain regions. The method for forming the doped regions 208 is using the mask patterns 202 as a mask to perform an ion implantation process on the substrate 200, for example.

Then, a plurality of dielectric patterns 210 is respectively formed on the pad oxide layer 206 above the doped regions 208. The method for forming the dielectric patterns 210 is by first forming a dielectric layer (not illustrated) which is made of silicon oxide for example, filling the trenches 204, which is on the pad oxide layer 206, by performing a chemical vapor deposition process, then removing a part of the dielectric layer outside of the trenches 204. It is noted that the step of partially removing the dielectric layer is by performing a chemical mechanical polishing process, for example.

Thereafter, with reference to FIG. 3C, the mask patterns 202 are removed. The method for removing the mask patterns 202 is by performing a wet etching process, for example.

Moreover, in order to effectively control the thickness and the quality of a tunneling dielectric layer, a part of the pad oxide layer 206 between the dielectric patterns 210 is removed and then a first electric layer 212 is formed on the substrate 200 between the dielectric patterns 210 for serving as the tunneling dielectric layer. The method for removing the pad oxide layer 206 is performing a wet etching process, for example. The method for forming the first dielectric layer 212 is performing a thermal oxidation process, for example.

Thereafter, a spacer 214 is formed on sidewalls of each of the dielectric patterns 210 respectively. The method for forming the spacers 214 is by forming a conductive layer (not illustrated), which is made of polysilicon for example, covering the dielectric patterns 210 by performing a chemical vapor deposition process on the substrate 200, then performing an etch-back process on the conductive layer. It should be noted that the etch-back process performed on the conductive layer is, a dry etching process for example, where the etchant comprises, for example, Chlorine (Cl₂) or Fluorine (F).

Next, with reference to FIG. 3D, a second dielectric layer 216 is formed on the spacers 214. The second dielectric layer 216 is, for example, a single-layered silicon oxide layer formed by performing the thermal oxidation process. Certainly, the second dielectric layer 216 can also be a silicon nitride layer, a silicon oxide/silicon nitride compound layer, a silicon oxide/silicon nitride/silicon oxide compound layer or other suitable film layers. The foregoing steps for forming the material layer of the second dielectric layer 216 comprise, for example, performing the thermal oxidation process and the chemical vapor deposition process.

After that, another conductive layer (not illustrated), made of polysilicon for example, is formed on the substrate 200 and covers the second dielectric layer 216. The method for forming the conductive layer is, for example, by performing the chemical vapor deposition process.

Thereafter, a patterning process implemented on the conductive layer and the spacers 214 includes, for example, a photolithography process and a etching process, whereby the conductive layer is patterned into conductor patterns 218 and the conductive layer serves as a control gate, and meanwhile, the spacers 214 are patterned into a plurality of spacer patterns 220 as floating gates, wherein the conductor patterns 218 cover the spacer patterns 220.

Accordingly, since the spacer patterns 220 are formed by using the method for fabricating the spacers, the process complexity and the process time for forming the spacer patterns 220 are effectively reduced. Therefore, the memory structure capable of storing two bits of data in the single cell can be fabricated by using a simple fabricating process.

In summary, the present invention has at least the following advantages:

1. The memory structure provided by the present invention can store two bits of data in the single memory cell.

2. The memory structure provided by the present invention has high capacity of memory cells.

3. The fabricating method for the memory structure provided by the present invention can effectively reduce the process complexity and the process time for fabricating the floating gates.

4. The memory structure for storing two bits of data in the single memory cell can be easily fabricated by using the fabricating method for the memory structure provided by the present invention.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A memory structure, comprising:
a substrate;
a plurality of dielectric patterns disposed on the substrate;
a plurality of spacer patterns respectively disposed on sidewalls of each of the dielectric patterns;
a first dielectric layer disposed between the spacer patterns and the substrate;
a conductor pattern disposed on the substrate and covering the spacer patterns;
a second dielectric layer disposed between the spacer patterns and the conductor pattern; and
a plurality of doped regions respectively disposed in the substrate under each of the dielectric patterns.

2. The memory structure as claimed in claim 1, wherein the substrate comprises a silicon substrate.

3. The memory structure as claimed in claim 1, wherein a material of the dielectric patterns comprises silicon oxide.

4. The memory structure as claimed in claim 1, wherein a material of the spacer patterns comprises polysilicon.

5. The memory structure as claimed in claim 1, wherein a material of the first dielectric layer comprises silicon oxide.

6. The memory structure as claimed in claim 1, wherein a material of the conductor pattern comprises polysilicon.

7. The memory structure as claimed in claim 1, wherein the second dielectric layer comprises a silicon oxide/silicon nitride/silicon oxide compound layer.

8. A fabricating method for a memory structure, comprising:
forming a plurality of doped regions on a substrate;
forming a first dielectric layer on the substrate;
forming a plurality of dielectric patterns on the substrate above the doped regions respectively;
forming a spacer on each sidewall of each of the dielectric patterns respectively;
forming a second dielectric layer on the spacers;
forming a first conductive layer on the substrate, the first conductive layer covering the second dielectric layer; and
performing a first patterning process on the first conductive layer and the spacers.

9. The fabricating method for a memory structure as claimed in claim 8, wherein the method for forming the doped regions comprises:
forming a plurality of mask patterns on the substrate;
using the mask patterns as a mask and performing an ion implantation process on the substrate; and
removing the mask patterns.

10. The fabricating method for a memory structure as claimed in claim 9, wherein the method for forming the mask patterns comprises:
forming a mask layer on the substrate; and
performing a second patterning process on the mask layer.

11. The fabricating method for a memory structure as claimed in claim 8, wherein the method for forming the dielectric patterns comprises:
forming a plurality of mask patterns on the substrate, a trench being formed between two adjacent mask patterns;
forming a third dielectric layer on the substrate, the third dielectric layer filling up the trenches;
removing a part of the third dielectric layer outside of the trenches; and
removing the mask patterns.

12. The fabricating method for a memory structure as claimed in claim 11, wherein the method for removing the part of the third dielectric layer comprises performing a chemical mechanical polishing process.

13. The fabricating method for a memory device as claimed in claim 8, wherein the method for forming the first dielectric layer comprises performing a thermal oxidation process.

14. The fabricating method for a memory structure as claimed in claim 8, wherein the method for forming the spacers comprises:
forming a second conductive layer on the substrate, the second conductive layer covering the dielectric patterns; and
performing an etch-back process on the second conductive layer.

15. The fabricating method for a memory structure as claimed in claim 14, wherein the method for forming the second conductive layer comprises performing a chemical vapor deposition process.

16. The fabricating method for a memory structure as claimed in claim 14, wherein the etch-back process comprises a dry etching process.

17. The fabricating method for a memory structure as claimed in claim 8, wherein the second dielectric layer comprises a silicon oxide layer, a silicon nitride layer or a silicon oxide/silicon nitride/silicon oxide compound layer.

18. The fabricating method for a memory structure as claimed in claim 8, wherein the method for forming the first conductive layer comprises performing a chemical vapor deposition process.
